(19) United States
(12) Patent Application Publication
(10) Pub. No.: US 2026/0107782 A1
(43) Pub. Date: Apr. 16, 2026

(54) MULTI-LAYER ALIGNMENT SYSTEM AND METHOD

(71) Applicant: Tokyo Electron Limited, Tokyo (JP)

(72) Inventors: Shuyan Zhang, Fremont, CA (US); Francisco Machuca, Fremont, CA (US)

(21) Appl. No.: 19/012,677

(22) Filed: Jan. 7, 2025

Related U.S. Application Data
(60) Provisional application No. 63/707,860, filed on Oct. 16, 2024.

(51) Int. Cl. H01L 23/544; H01L 21/66; H01L 21/68

(52) U.S. Cl. CPC H10W 46/00; H10P 72/53; H10P 74/235; H10W 46/301

(57) ABSTRACT

A semiconductor structure includes a first layer, a second layer, and a third layer bonded together in a multi-layer stack. The first layer includes a first alignment section, the second layer includes a second alignment section, and the third layer includes a third alignment section and a fourth alignment section. The third alignment section is along a first X-ray path with the first alignment section and the fourth alignment section is along a second X-ray path with the second alignment section.

### CROSS-REFERENCE TO RELATED APPLICATIONS

This application claims the benefit of U.S. Provisional Application No. 63/707,860, filed on Oct. 16, 2024, and entitled, “Alignment Marks for X-ray Interferometric Die-to-Die and Die-to-Wafer Multilayer Bonding,” which application is hereby incorporated herein by reference in its entirety.

### TECHNICAL FIELD

The present disclosure relates generally to semiconductor fabrication, and, in particular implementations, to X-ray methods and systems for multi-layer alignment.

### BACKGROUND

Generally, a semiconductor integrated circuit (IC) is fabricated by sequentially depositing conductive, dielectric, and semiconductor layers over a semiconductor substrate to form IC devices. Semiconductor processing includes patterning layers using photolithography and etch to form electronic and interconnect elements like transistors, resistors, capacitors, metal lines, contacts, and vias in one monolithic structure.

The semiconductor industry has traditionally followed Moore's Law, which was initially based on the observation that the number of transistors on a chip doubles approximately every two years, leading to a cadence of shrinking feature sizes (also referred to as “scaling”) along with improvements in performance and reductions in costs. However, as transistor features approached atomic dimensions, maintaining this pace has become increasingly challenging. As a result, the scaling cadence has evolved from a strict focus on feature size reduction to a more complex progression incorporating innovations in 3D structures, new materials, and integration methods.

The advancement toward miniaturization in semiconductor technology has been a driving force behind the development of sophisticated 3D integration techniques such as wafer-to-wafer (W2W) bonding, die-to-die (D2D) bonding, die-to-wafer (D2W) bonding, along with multi-die stacking, including such examples as dynamic random access memory (DRAM) and advanced High Bandwidth Memory (HBM) having up to 16 layers or more. The success of 3D integration processes can be contingent upon a precise alignment of components to provide good electrical performance and mechanical anchoring, such as to support high density interconnect schemes. Such precise alignment using traditional optical alignment methods can become increasingly difficult to perform, particularly when dealing with opaque materials presented by thick substrate layers of doped silicon (Si) and multiple metallized copper layers, and in cases where initial alignment marks are optical (e.g., a mark on the underside of a die, and a mark on the top side of the substrate or target die in multi stacked structures) and are forced to be offset because the substrate mark would be occluded to detection post bonding. This also buries the die bonding alignment fiducial with metallization above it, making it not visible to infrared (IR) imaging techniques because (IR) light cannot penetrated and so offset tolerance stack-up errors may add up.

These limitations become even more pronounced in highly stacked configurations, such as in High Bandwidth Memory (HBM) or static RAM (SRAM) on large-scale integration (LSI) platforms with 16 layers in state of the art that may rapidly progress to 20 or more layers.

### SUMMARY

In accordance with an embodiment, a semiconductor structure includes a first layer, a second layer, and a third layer bonded together in a multi-layer stack, the first layer including a first alignment section, the second layer including a second alignment section, and the third layer including a third alignment section and a fourth alignment section, the third alignment section being along a first X-ray path with the first alignment section, and the fourth alignment section being along a second X-ray path with the second alignment section.

In accordance with another embodiment, a method for multi-layer alignment includes: applying a respective alignment mark to each layer of a plurality of layers, the plurality of layers including at least three layers; directing X-rays to the respective alignment marks of each layer of the plurality of layers, the plurality of layers being in a bonding configuration; and identifying a misaligned layer in the plurality of layers by measuring interference patterns generated by the X-ray.

In accordance with yet another embodiment, a system for multi-layer alignment includes: a multi-layer stack, the multi-layer stack including a plurality of layers in a bonding configuration, each layer of the plurality of layers including a respective Moiré alignment mark; and an X-ray imager configured to: direct X-rays to the respective Moiré alignment marks, and identify a misaligned layer in the plurality of layers by measuring interference patterns generated by the X-rays.

It is to be understood that both the foregoing general description and the following detailed description are exemplary and explanatory only and are not restrictive of the disclosure, as claimed.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates an X-ray measurement system, in accordance with some embodiments;

FIG. 2A illustrates an X-ray measurement system, in accordance with some embodiments;

FIG. 2B illustrates intensity and phase sensitivity as a function of thickness for different materials and X-ray energies, in accordance with some embodiments;

FIGS. 3A and 3B illustrate a simplified schematic of an exemplary multi-layer stack, in accordance with some embodiments;

FIG. 4 illustrates an alignment mark that comprises horizontal and vertical unit cells, in accordance with some embodiments;

FIGS. 5A, 5B, and 5C illustrate correlation of misalignment between layers with Moiré pattern shift, in accordance with some embodiments;

FIG. 6 illustrates a contrast improvement method, in accordance with some embodiments;

FIGS. 7, 8A, 8B, 9A, 9B, 10A, 10B, and 11 illustrate an alignment mark layout system for a normal incidence X-ray beam, in accordance with some embodiments;

FIGS. 12A, 12B, 13A, and 13B illustrate an alignment mark layout system for an oblique incidence X-ray beam, in accordance with some embodiments; and

FIG. 14 illustrates a process flow chart diagram of a method for multi-layer alignment, in accordance with some embodiments.

Corresponding numerals and symbols in the different figures generally refer to corresponding parts unless otherwise indicated. The figures are drawn to clearly illustrate the relevant aspects of the embodiments and are not necessarily drawn to scale. The edges of features drawn in the figures do not necessarily indicate the termination of the extent of the feature.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

High-throughput advanced alignment and defect metrology are desirable for multi-die stacks, such as stacks in which the number of stacked dies can range from 3 to 16, and alternatively from 3 to higher than 16. This disclosure describes X-ray methods and systems for semiconductor substrate alignment, such as for aligning two or more semiconductor substrates for a 3D bonding process, in various implementations.

This disclosure introduces the use of advanced alignment marks for forming multi-die Moiré (interference) patterns, in conjunction with spatially coherent X-ray illumination. The X-ray coherence may be achieved in various ways and using many known techniques, including but not limited to propagation-based imaging techniques and Talbot-Lau X-ray multi-modal imaging. Various examples of bonding processes with X-ray based alignment are described in U.S. patent application Ser. No. 18/419,733, and various examples of using alignment marks in conjunction with X-ray Talbot-Lau interferometers are described in U.S. patent application Ser. No. 18/620,463, which applications are hereby incorporated by reference in their entireties. X-ray imaging using hard X-rays may provide better penetration through opaque materials, allow imaging across different materials with varying refractive indices, and provide consistent focus across thick multilayer structures (effectively an infinite depth of field). As memory devices continue to increase in complexity, the adoption of X-ray imaging for multi-die alignment may be advantageous for continued improvement of device performance, power, area, and cost (PPAC), as well as yield, and for process control to feedforward the degree of stack for subsets of the stack and then make corrections in subsequent subsets of the total stack for recentering and subsequently building high (for example, at every fourth layer to build a stack of 16 layers).

An advantage of embodiments of this disclosure is that the Moiré pattern effect is utilized not only to quantify shifts and deduce misalignments for process control in direct metal-metal bonding (e.g., Cu—Cu bonding), down to the nanometer scale, but also to derive layer by layer identification or tags, per die, using multilayer Moiré patterns to determine exactly which die or dies in the stack are shifted. This capability is useful when multiple dies are stacked together in groups or subsets of the total height of stacks or if the number of dies within a stack is large (e.g., twelve or more dies), as it allows for several advantageous actions: (a) correcting the stack as it is being bonded, if reworkable, (b) voting the stack as bad and preventing it from being stacked on top of a Known Good Die (KGD) or Known Good (KG) stack of other memory, (c) feeding forward and fixing the measured die shift to the next bonding step, (d) using the information for stack binning and downgrading the die stack, and/or deciding if the stack is reworkable, or (e) measuring drift of the bonding tool before it goes out of process latitude so that corrective action can be taken such as realignment of probe heads or other PM (preventive maintenance). Additionally, the system allows for per-layer defect inspection in one imaging view, focusing on metal-metal (e.g., Cu—Cu) contact defects and other defects. Without loss of generality, the disclosure herein may be applied to conventional thermal compression and other bonding techniques in advanced packaging. Hereinafter, the terms die and layer will be used interchangeably, where a layer may also comprise a wafer, typically at the bottom of a die stack.

This disclosure presents a system and method for achieving highly accurate multi-die alignment and defect detection in bonding processes such as metal-metal (e.g., Cu—Cu) 3D integrated direct bonding (e.g., hybrid bonding) for memory devices and advanced stacked memory on logic. The system employs multi-level Moiré patterns to detect misalignments with a Moiré magnification factor that allows for nanometer-scale precision while also uniquely identifying the specific layer (i.e. die) within the stack that is misaligned. In other words, the system enables layer ID. This is advantageous when stacking multiple die simultaneously or having a large number of dies to index, such as in HBM or SRAM on LSI platforms. The system also enables per-layer ID to assign the corresponding outcomes from defect inspection, focusing on good metal-metal (e.g., Cu—Cu) contact to ensure electrical integrity of the full stack.

In various embodiments, a Talbot-Lau X-ray system is used, employing a grating-based interferometric setup to capture absorption (or transmission), phase contrast (or differential phase contrast), and small-angle scatter (or dark field) images in one single shot. In various other embodiments, a spatially coherent source and projected distance are used to develop phase contrast and small angle scatter using propagation-based imaging. In any of these embodiments, but not limited to these forms of phase sensitive X-ray detection, the system can detect nanometer-scale misalignments with high precision by analyzing the Moiré patterns generated by the alignment mark. This can ensure that multiple die are properly aligned both during the bonding process and in post-bonding validation. Hard X-ray phase contrast imaging and full field imaging small angle X-ray scatter (FFI-SAXS) methods offer superior depth penetration and the ability to detect and correct misalignments and catch defects across multiple dies, including defects sandwiched between two bonded pads of opaque material, like Cu and defects in dielectric material such as SiO₂ or tetraethyl orthosilicate (TEOS). The feedback mechanism of the system supports real-time correction during the bonding process, followed by post-bonding inspection/validation and voting/decision-making for die binning, rework, or flagging die stacks as bad. In some examples, this can be integrated with the bond head and the act of bonding can be interrogated simultaneously with the action of bonding, improving the measurement cycle for fast high volume manufacturing (HVM) applications. This may be advantageous over other approaches in which, for example, bonding is done optically with visible cameras and validation is done subsequently and separately with IR imaging. Proposed herein is a unique Moiré pattern design of the alignment mark with a dual-row differential pair Moiré grating as the unit cell, to take advantage of the Moiré fringe magnification factor to detect die overlay error at the nanometer scale.

In normal X-ray incidence embodiments, the alignment marks are different for each die to be bonded. Each top die is aligned with the bottom die, or other reference die, and the alignment marks are spatially separated in the plane of each mask layout. Embodiments include but are not limited to a double “basket weave” layout, a combination of stacked/running bond, stack bond, etc.

In oblique X-ray incidence embodiments, the alignment marks are the same for each die, such as to avoid additional mask cost to print different patterns per layer, and are located at the same spatial coordinates within a die. When the X-ray source is tilted at a specific oblique incidence angle with respect to the die normal axis, one section (e.g., a left section) of a die alignment mark of a layer is overlapped with another section (e.g., a right section) of the die alignment mark of the next lower neighboring layer, along the beam path. The sections of alignment marks, such as left sections and right sections, are also referred to as alignment sections. The projected overlapped alignment mark images form a Moiré pattern that is the same as in the normal incidence case. Advantages of the oblique incidence X-ray beam configuration are: (1) the alignment mark is the same on each die, so fabrication complexity and cost are reduced, (2) the total alignment mark size is much smaller than in the normal X-ray incidence case because the spatial separation required to match a die in a stack to the final multilayer alignment mark image in the detector image is determined by the tilted projection. In other words, the tilt uniquely separates out all die in the stack laterally, enabling die identification based on lateral position in the detected image.

While the following description of alignment marks and associated methods is presented using an exemplary 16-layer die stack, all the embodiments, methods, and systems described herein can be generalized to any number of stacked die layers of 3 or greater, and in some embodiments greater than 16. Similarly, the embodiments, methods, and systems can be generalized for other materials than silicon (Si) die and wafers and copper (Cu) for contacts and/or alignment marks. For example, disclosed embodiments, methods, and systems may be advantageous for applications including non-silicon substrates for heterogeneous integration involving, for example, III-V compound semiconductors such as GaAs, GaN, SiC, or the like that integrate power or high speed devices with silicon logic, or for optical interconnects with silicon logic and silicon memory.

In various embodiments, the metrology system comprises a Talbot-Lau X-ray multi-modal imaging setup, including an X-ray source, a phase grating, one or two amplitude gratings, and a high-resolution X-ray detector. Such a setup is capable of capturing absorption, phase contrast, and small-angle scatter images simultaneously. Alternatively, the system may comprise a highly collimated X-ray source with a projection setup, including a high-power X-ray source, a collimator, and a high resolution X-ray detector. The latter setup is also capable of capturing multi-modal X-ray images in a single shot.

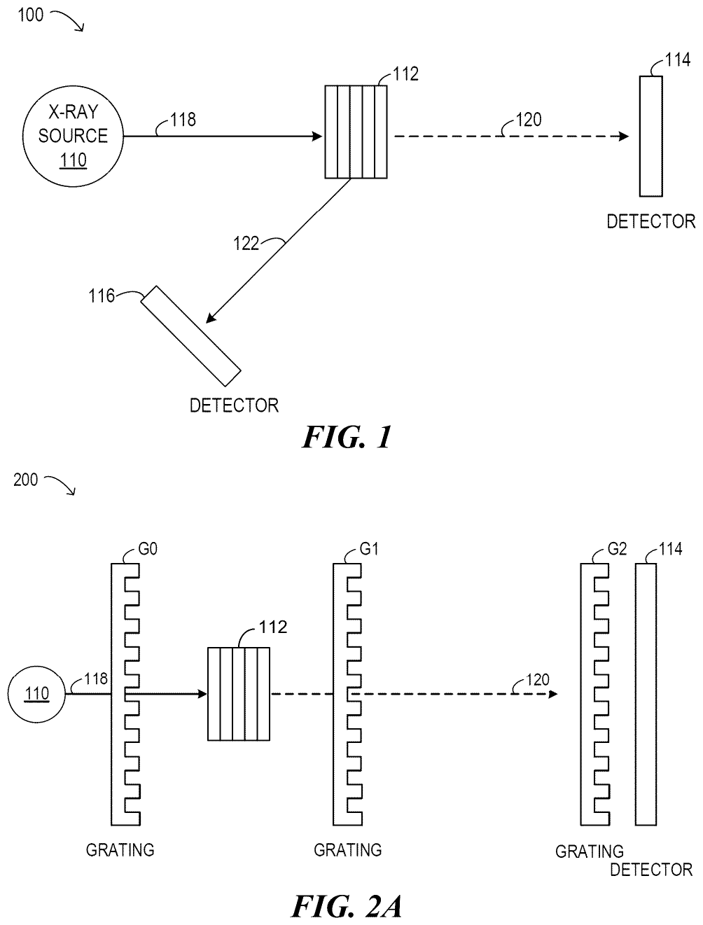

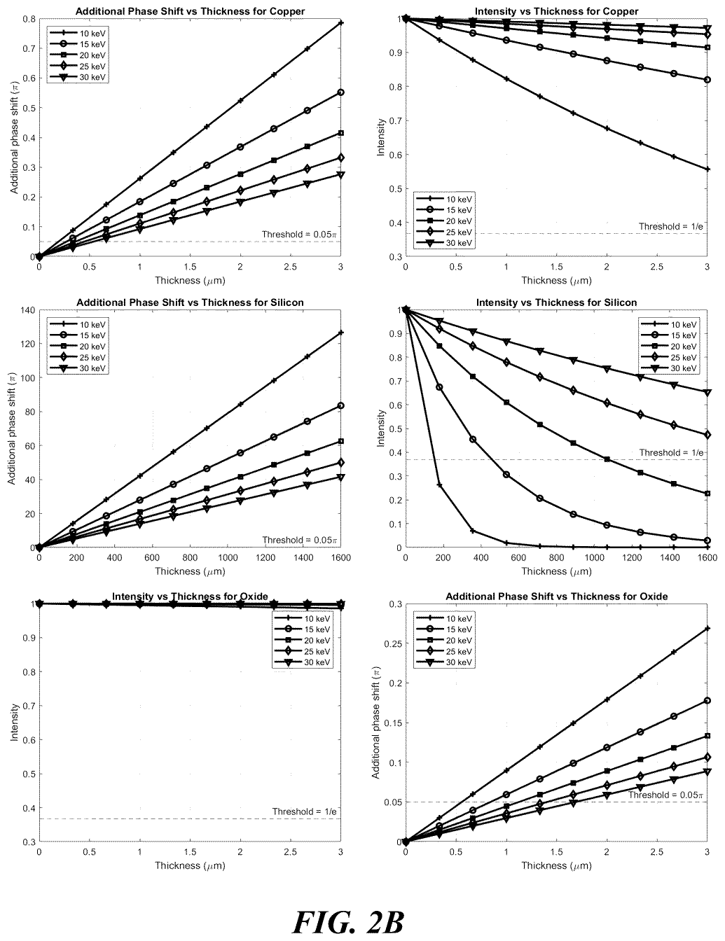

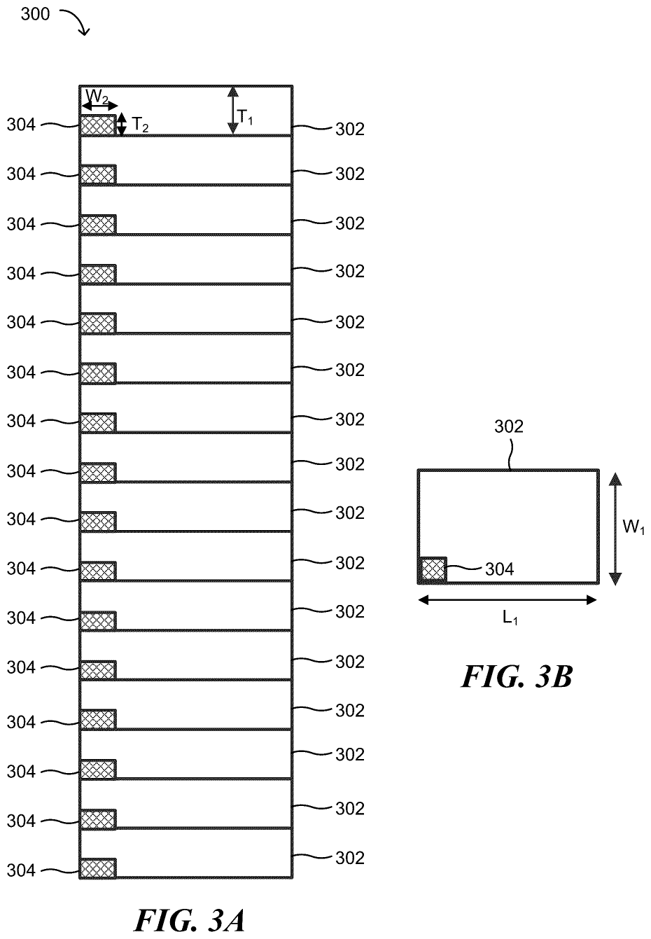

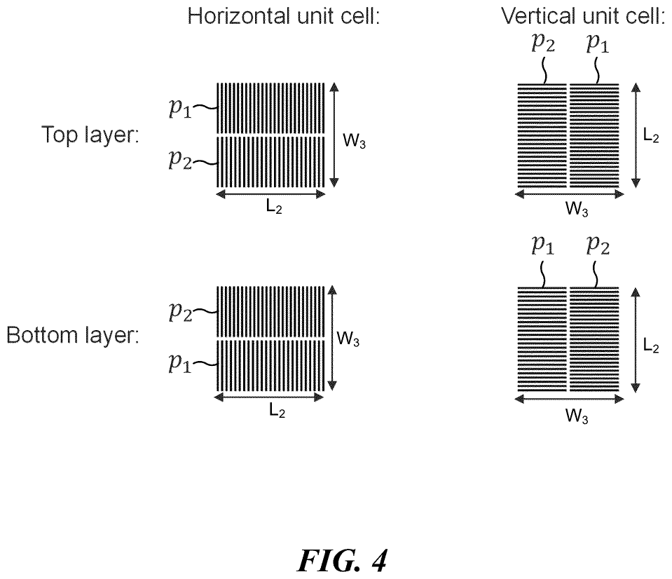

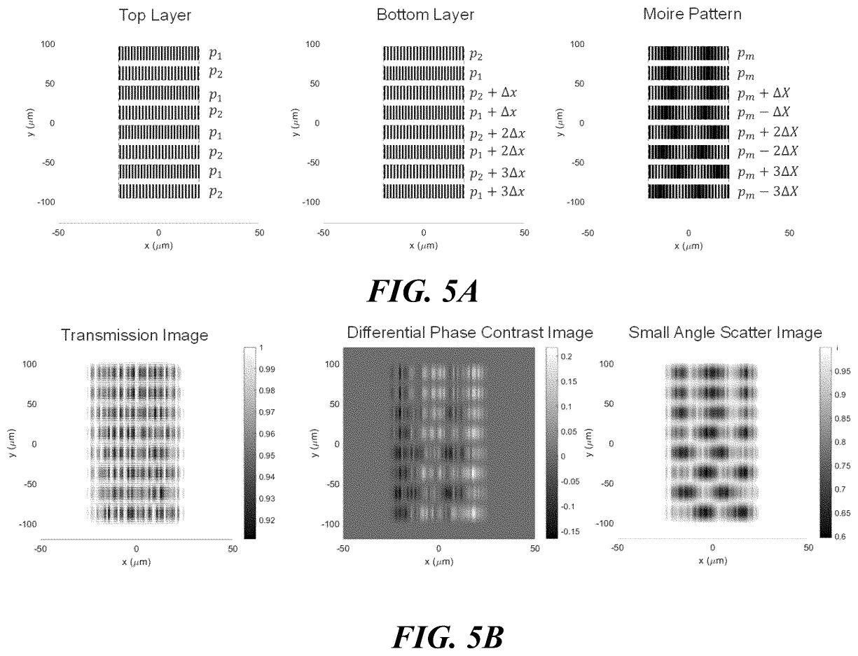

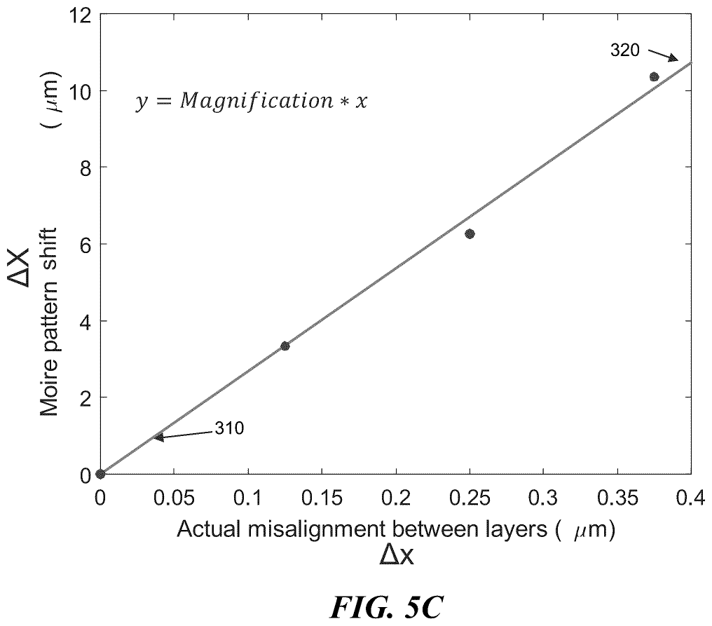

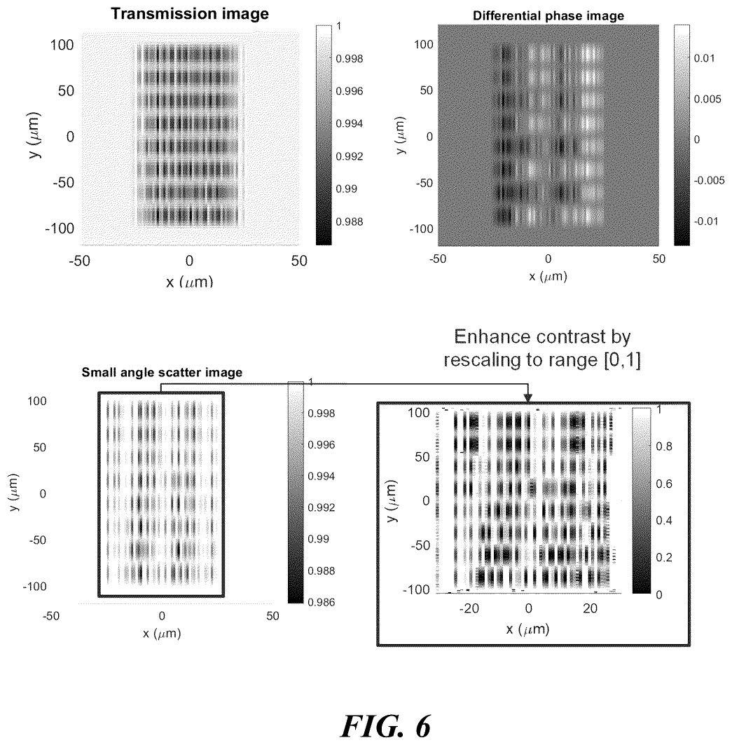

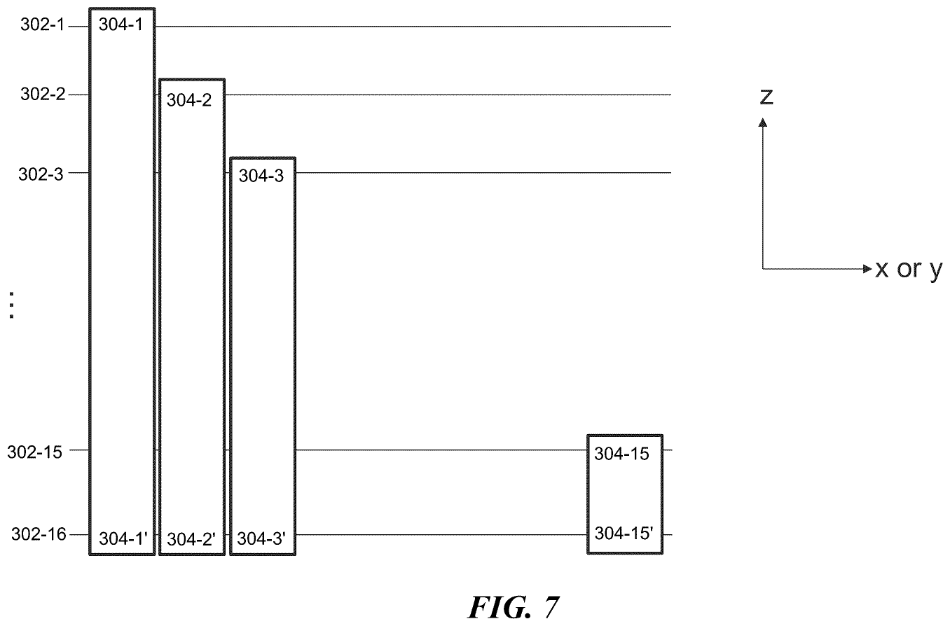

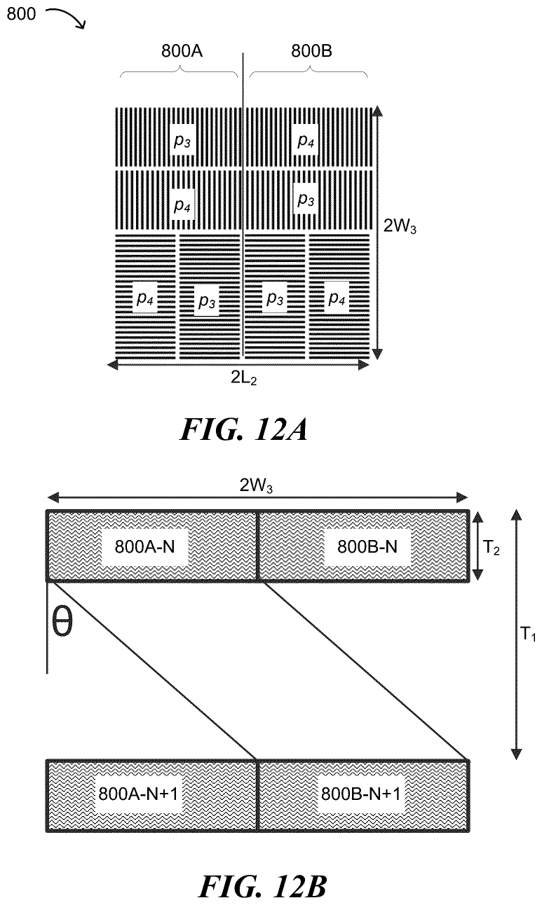

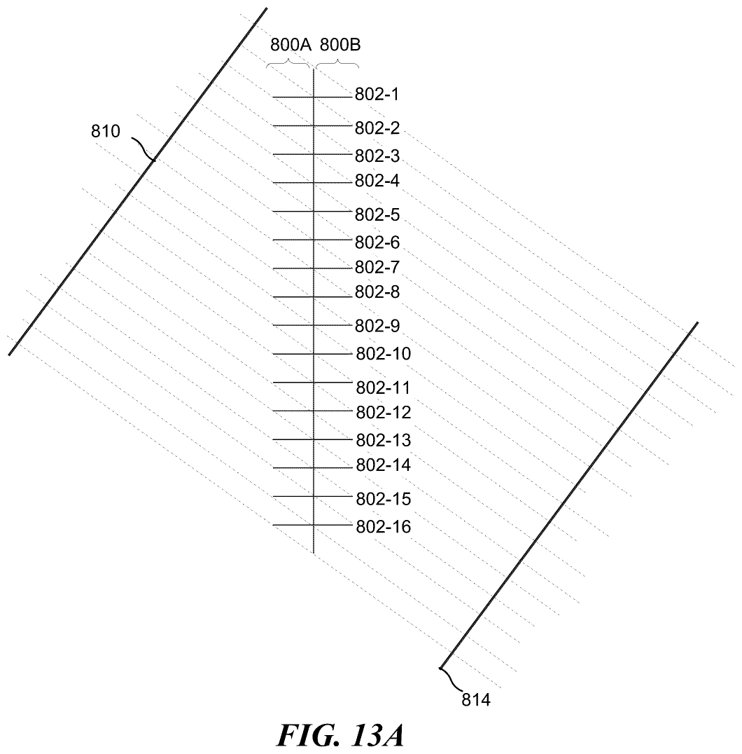

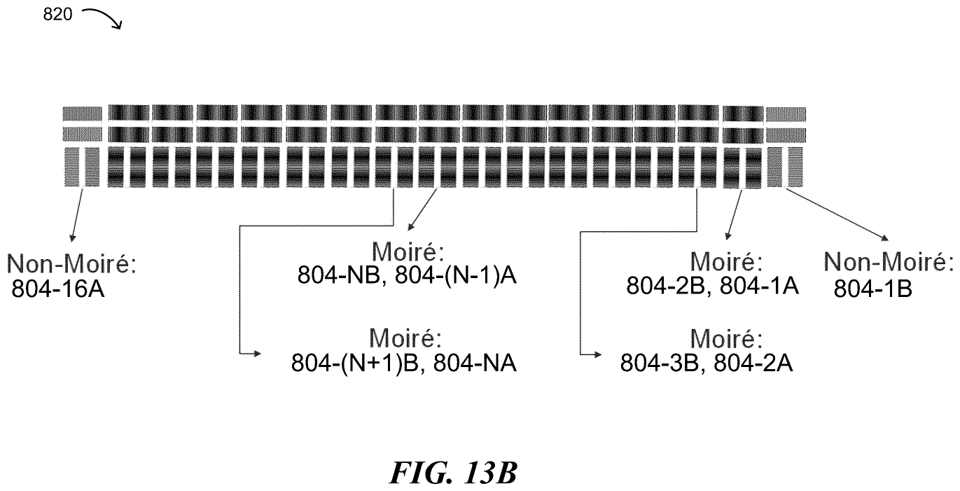

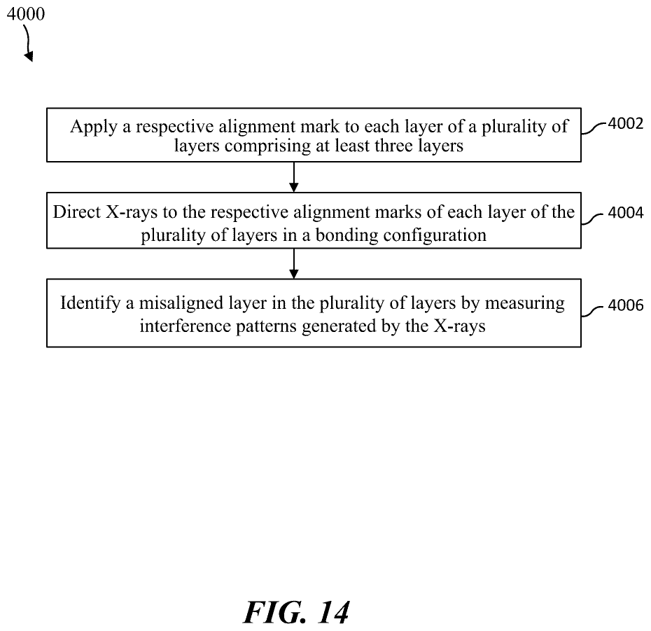

Embodiments of the disclosure are described in the context of the accompanying drawings. Embodiments of X-ray measurement systems will be described using FIGS. 1, 2A, and 2B. An embodiment of a multi-layer stack will be described using FIGS. 3A and 3B. An embodiment of an alignment mark comprising horizontal and vertical unit cells will be described using FIG. 4. Embodiments of determining correlation of misalignment between layers with Moiré pattern shift will be described using FIGS. 5A, 5B, and 5C. An embodiment of a contrast improvement method will be described using FIG. 6. Embodiments of alignment mark layout systems for a normal incidence X-ray beam will be described using FIGS. 7, 8A, 8B, 9A, 9B, 10A, 10B, and 11. Embodiments of alignment mark layout systems for an oblique incidence X-ray beam will be described using FIGS. 12A, 12B, 13A, and 13B. An embodiment of a method for multi-layer alignment will be described using FIG. 14.

FIG. 1 illustrates an exemplary dual X-ray measurement system 100 (also referred to as a system 100 for multi-layer alignment or simply system 100). FIG. 1 is a schematic illustration and is not necessarily drawn to scale or perspective. Certain elements are omitted in FIG. 1 for descriptive clarity.

System 100 in FIG. 1 comprises an X-ray source 110 that can output an X-ray beam 118 towards a multi-layer stack 112. X-ray beam 118 can comprise incoherent X-rays or coherent X-rays having a defined frequency, wavelength, and phase. Multi-layer stack 112 can represent a test sample or a test object and comprises, for example, three or more layers (e.g., semiconductor substrates) that are to be bonded. Although FIG. 1 illustrates the multi-layer stack 112 with five layers, the multi-layer stack 112 may have any suitable number of layers, such as 3 to 16 layers, or more than 16 layers. In various embodiments, the layers of the multi-layer stack 112 are subject to analysis and measurement of misalignment to each other using system 100, as described in further detail herein. In some embodiments, the multi-layer stack 112 can be used with system 100 in a bonding process prior to bonding, such as when various layers of the multi-layer stack 112 are held in a fixture in proximity to each other and are in a process of pre-bonding alignment.

Accordingly, system 100 also comprises a first detector 114 that receives transmitted X-ray beam 120 from the multi-layer stack 112 and comprises a second detector 116 that receives backscattered X-rays 122 from the multi-layer stack 112. As shown, backscattered X-rays 122 can comprise fluorescent X-rays that are emitted from the multi-layer stack 112 in response to irradiation of the multi-layer stack 112 by X-ray beam 118. When the atoms in the multi-layer stack 112 absorb the energy from the irradiating X-ray beam 118, their electrons are ejected from the inner shells (typically the K or L shells). Eventually, the electrons from higher energy levels (outer shells) fall into the lower energy vacancies. As an electron transitions from a higher energy level to a lower one, energy is released in the form of fluorescent X-rays. The emitted fluorescent X-rays have characteristic energies that are specific to each element. Two methods for measuring these X-rays are Energy Dispersive X-ray Fluorescence (EDXRF) and Wavelength Dispersive X-ray Fluorescence (WDXRF). EDXRF uses a semiconductor detector to directly measure the energy of the incoming fluorescent X-rays, thereby discerning different elements. WDXRF uses a crystal to disperse the X-rays onto a detector according to their wavelength, with detectors then measuring their intensity.

Various types of X-ray detectors can be used as first detector 114. In particular, semiconductor X-ray detectors can be used for first detector 114, such as direct detection by a flat panel X-ray detector having good spatial resolution and X-ray absorbing properties, such as a semiconductor flat panel imaging array that can generate image data from received X-rays or a CMOS image sensor paired with a scintillator, or a hybrid detector with a heavy atomic number semiconductor coupled to CMOS or photodiode array for detection. It is desirable for high spatial resolution to achieve micron or submicron resolving power of the image modalities for phase (or phase shift) or small-angle scatter (or dark field).

In various embodiments, the second detector 116 can be an X-ray fluorescence (XRF) detector, such as a Silicon Drift Detector (SDD) that can measure energy (wavelength) and intensity of incident X-ray photons in backscattered X-rays 122. A Silicon Drift Detector (SDD) is an Energy Dispersive X-ray Fluorescence (EDXRF) detector. Second detector 116 can comprise a high-purity silicon wafer that acts as the detection material. When X-rays enter the silicon wafer, they interact with the silicon atoms and generate electron-hole pairs proportional to the energy of the X-rays. The wafer has a series of ring-shaped electrodes, or drift rings, on its surface. These are concentrically arranged around a small collection anode in the center. The rings create a potential gradient when voltage is applied, which ensures that the generated charge carriers (electrons) drift towards the center. The charge carriers that are created by the interaction of X-rays with the silicon wafer drift towards the collection anode due to the presence of an electric field. A Field-Effect Transistor (FET) is coupled to the collection anode at the center of the silicon wafer. This FET amplifies the signal generated by the incident X-rays as soon as the charges arrive at the collection anode. After initial amplification, the signal goes through further processing stages, where it is shaped, amplified, and converted into a digital signal. The energy of each incident X-ray photon is proportionate to the charge pulse height produced by the detector, thereby enabling energy measurement.

In various embodiments, system 100 is capable of providing output signals from first detector 114 and second detector 116 simultaneously in response to X-ray beam 118 interacting with the multi-layer stack 112.

As noted, various other elements and components for X-ray measurement system 100 are omitted from FIG. 1 for descriptive clarity. For example, system 100 may operate in a vacuum environment, such as in a vacuum chamber in a semiconductor fabrication process. X-ray source 110 can include various means for filtering or directing X-ray beam 118 towards the multi-layer stack 112. In particular implementations, X-ray beam 118 is generated using a Mo anode with a 17.5 keV characteristic wavelength, or Rhodium anode with 20 keV characteristic wavelength, or a copper (Cu) target, at around 8-9 keV energy, among other potential targets and energy bands in various implementations. When X-ray beam 118 is generated using the Cu target at around 8-9 keV, XRF can be performed through a Si substrate in the multi-layer stack 112 having a thickness of about 50 nm to about 100 μm in order to avoid excessive self-absorption of X-rays, such as for D2D and D2W bonding in a face-to-face or back-to-face arrangement, in which a first die to be bonded (e.g., a first layer of the multi-layer stack 112) can receive incident X-ray beam 118 at a back surface or a face surface.

FIG. 2A is an illustration of an X-ray measurement system 200 (or simply system 200) using Talbot-Lau interferometry, in accordance with some embodiments. As shown in FIG. 2A, system 200 represents a partial configuration of dual X-ray measurement system 100 in FIG. 1 illustrating three gratings used for Talbot-Lau interferometry. The Talbot-Lau interferometer setup generally comprises the three gratings shown in system 100, including a source modulation grating G0, a beam splitter grating G1, and an analyzer grating G2. In some embodiments, source modulation grating G0 can be omitted when X-ray beam 118 has a long coherence length, such as when X-ray source 110 is a synchrotron or when the source contains a patterned anode that could effectively acts as a source modulation grating G0. Source modulation grating G0, also known as an X-ray mask, can be placed close to the X-ray source. Source modulation grating G0 is designed to create an array of line sources by blocking parts of the X-ray beam, effectively producing partially coherent radiation from an incoherent source, like a conventional X-ray tube.

Beam splitter grating G1, also referred to as a phase grating G1, generates a periodic interference pattern that can have maximum intensity oscillations. Phase grating G1 is located downstream of source modulation grating G0, such as at a specific distance. The phase-shift caused by phase grating G1 leads to the creation of an interference pattern known as the Talbot carpet some distance away in the absence of a sample between gratings G0 and G1. In various examples, G1 introduces a π/2 or π phase shift. Thus, a periodicity of the Talbot carpet can be a property of system 200 itself for any sample used.

The third component in system 200 is an analyzer grating G2, also referred to as an absorption grating G2, placed at one of the self-image planes of the Talbot carpet, which may correspond to a fractional Talbot distance. Analyzer grating G2 has periodic absorbing structures that can translate slight changes in interference fringes into intensity changes at first detector 114. The periodicity of the Talbot carpet in system 200 can be matched to a pitch of analyzer grating G2 to optimize sensitivity of displacement measurements of a sample, such as misalignment measurements of the multi-layer stack 112. In some embodiments, analyzer grating G2 can also be omitted, such as when first detector 114 has a spatial or pixel resolution that is substantially smaller than the interference fringes.

In the system 200 illustrated in FIG. 2A, analyzer grating G2 converts phase shifts into intensity variations (amplitude modulation), making the phase shifts detectable by first detector 114, for example. The pattern at the plane of first detector 114 carried by X-ray beam 120 can thus include information about the absorption, phase shift, and small-angle scattering caused by the sample (e.g., the multi-layer stack 112). When the sample (e.g., the multi-layer stack 112) is placed between phase grating G1 and analyzer grating G2, the X-ray interaction with the sample alters the interference pattern due to the modulation of the phase of incoming X-ray beam 118. The local changes in absorption, phase, and small-angle scattering lead to corresponding modifications in the intensity pattern in X-ray beam 120 that are measured by first detector 114 located behind analyzer grating G2. In practice, a series of images can be taken while laterally shifting one of phase grating G1/analyzer grating G2, such as across a fractional or one or several periods. For example, when the signal to noise ratio is large, scanning across 1/2 or 1/4 of a period may be sufficient. This step scanning process allows a reconstruction of differential phase contrast and dark-field images in addition to the standard transmission image.

In operation, system 200 can employ Talbot-Lau interferometry and can analyze objects, such as e.g., the multi-layer stack 112, in transmission. For example, first detector 114 can be used to detect transmission signals for alignment marks located on one or more surfaces of layers of the multi-layer stack 112. Furthermore, when layers of the multi-layer stack 112 include interferometric alignment marks, such as Moiré interferometric patterns, that interact with X-ray beam 118, first detector 114 can be used to detect interferometric patterns associated with misalignment of the Moiré interferometric patterns. In particular embodiments, a displacement of the Moiré interferometric patterns that first detector 114 can detect can be directly linear with the misalignment of a layer of the multi-layer stack 112 with respect to a reference layer of the multi-layer stack 112, as will be described in further detail below with respect to FIGS. 5A-5C. The linear relationship can represent an effective magnification that system 200 can obtain from the Moiré interferometric patterns to increase sensitivity to the actual misalignment of layers of the multi-layer stack 112. The increased sensitivity to the actual misalignment can improve an accuracy of alignment of layers of the multi-layer stack 112 that can then be performed.

Furthermore, the Moiré interferometric patterns forming a Moiré interferometric grating pair can have a first grating orientation that can be aligned with a second grating orientation of beam splitter grating G1 and analyzer grating G2 to improve sensitivity or to achieve a maximum sensitivity for detecting a displacement of Moiré interferometric patterns relative to each other (e.g., detected misalignment). In order to detect and measure misalignment along different axes of the multi-layer stack 112, the multi-layer stack 112 can be rotated by a suitable angle that corresponds to grating orientations of different sets of Moiré interferometric grating pairs formed in layers of the multi-layer stack 112, such as 45°, 90°, 135°, 180°, 225°, and 315° rotations in various implementations.

FIG. 2B illustrates intensity and phase sensitivity as a function of thickness for copper, silicon, and oxide and X-ray energies. The intensity describes the transmission which is the percentage of the incident intensity. As such, the material thickness is increased, the intensity is lower due to larger material absorption of the X-rays. The phase sensitivity describes the phase delay introduced to the incident beam. The thicker the material, the larger the phase delay, and hence the higher the contrast (in other words, a stronger signal in phase contrast image modality). The threshold lines provide guidance for X-ray energy optimization. A desirable X-ray energy level should have minimal material absorption and larger phase delay. The intensity is related to the imaginary part of the refractive index of the material. The phase is related to the real part of the refractive index of the material.

In particular embodiments, X-ray beam 118 can have sufficient energy to penetrate thick Si substrates, including highly doped Si substrates, in order to perform Talbot-Lau interferometry using system 200. For example, the X-ray source kinetic energy range for hard X-rays may be from 8 to 70 keV. For extremely thin Si layers, X-rays with energy less than 8 keV may be utilized. Higher energy X-rays, in other words with energy up to 120 keV, may be used if the application benefits from higher energies, with a trade-off of contrast loss at energies higher than about 50 keV. The phase sensitivity is reduced as the X-ray energy is higher, as illustrated by FIG. 2B. For example, an optimized energy at 20 keV could provide penetration larger than 1000 μm of Si substrates and a phase sensitivity of 0.07π of 0.5 μm of Cu bonding pad material.

Accordingly, system 200 can be used to measure misalignment of the multi-layer stack 112 using X-ray Talbot-Lau interferometry in various applications, such as for D2D, D2W, and W2W bonding. Furthermore, the ability of X-ray beam 118 to measure misalignment of the multi-layer stack 112 when the multi-layer stack 112 includes thick or highly doped Si substrates using Talbot-Lau interferometry, as illustrated in FIG. 2A, can allow various relative semiconductor surface orientations of layers of the multi-layer stack 112 to be measured, including a face-to-face arrangement, a back-to-face arrangement, a face-to-back arrangement, and a back-to-back arrangement. Detected misalignments may be horizontal, vertical, or rotational misalignments. The system 200 can be further used to provide real-time feedback for correction of misalignment in the multi-layer stack 112 using the measured interference patterns, such as when the multi-layer stack 112 is in a bonding configuration but its layers have not been bonded or fully bonded together.

In various embodiments, the X-ray imager of systems 100 and/or 200, which may include the X-ray source 110, the first detector 114, and/or the second detector 116, is configured to direct X-rays to respective Moiré alignment marks of the multi-layer stack 112 and identify a misaligned layer in the plurality of layers by measuring interference patterns generated by the X-rays. In some embodiments, the X-ray imager is a Talbot-Lau multi-modal imager. In other embodiments, the X-ray imager is a propagation-based imager configured to use spatially coherent collimated X-rays. In some embodiments, the X-ray imager includes a projection transmission mode architecture that utilizes spatially coherent X-rays or small angle-scattered X-rays. In some embodiments, the X-ray imager has a reflection mode diffractometer architecture that utilizes spatially coherent X-rays or small angle-scattered X-rays. In some embodiments, the X-ray imager is further configured to remove absorption cross-section across a full range of energies in its illumination spectrum. In some embodiments, the X-ray imager is further configured to utilize phase coherence or small angle-scattered X-rays for a memory and LSI logic radiation damage free probe to identify the misaligned layer. In various embodiments, the X-ray imager is further configured to perform defect detection.

FIGS. 3A and 3B illustrate a simplified schematic of an exemplary multi-layer stack 300, also referred to as a semiconductor structure. FIG. 3A illustrates a side view of the multi-layer stack 300 and FIG. 3B illustrates a top view of a layer 302 with an alignment mark 304 in a corner of the layer 302. However, the alignment marks 304 may be in any suitable positions in the layers 302. In various embodiments, the layers 302 have lengths L₁ in a range of 1 mm to 75 mm, widths W₁ in a range of 1 mm to 75 mm, and thicknesses T₁ in a range of 20 μm to 400 μm.

As illustrated in FIG. 3A, the multi-layer stack 300 comprises sixteen layers 302 with respective alignment marks 304 placed at the bonding interface between the layers 302. The respective alignment mark 304 of the lowest layer 302 may be placed at a bottom surface of the lowest layer 302. However, the multi-layer stack 300 may comprise any suitable number of layers 302, such as three or more layers 302. In various embodiments, the layers 302 are dies made of silicon (Si). However, the layers 302 may be any suitable structure or material.

In some embodiments, the alignment marks 304 comprise a metal such as copper (Cu) or the like. However, the alignment marks 304 may comprise any suitable material. Moiré alignment marks for hard X-rays can be made from Cu or other suitable materials, such as Ni, W, Co, and Cr, which are all acceptable materials for use in semiconductor applications. In various embodiments of dual differential cases in which two gratings are overlaid to generate Moiré patterns, the alignment marks 304 have widths W₂ in a range of 1 μm to 200 μm, thicknesses T₂ in a range of 0.1 μm to 1 μm, and Moiré grating pitches in a range of 0.1 μm to 5 μm, where the width of the alignment mark corresponds to the combined width of the left and right sections in the oblique incidence case. In other embodiments, four or more gratings can be used to generate an interference of two or more Moiré patterns. For example, two dual differential sets of gratings p₁, p₂ and p₁′, p₂′ may be printed such that gratings p₁, p₂ produce a first Moiré pattern, gratings p₁′, p₂′ produce a second Moiré pattern, and the first and second Moiré patterns interfere. In still other embodiments, multiple layers of metal are added to the alignment marks to improve the signal to noise ratio of the Moiré patterns so that the thicknesses of the alignment marks are about double the thicknesses T₂ as described above. The multiple layers of metal may be overlaid with lithographic accuracy, such as with ±1 nm or better precision.

FIG. 4 illustrates a bonding fiducial mark used for alignment that comprises horizontal and vertical unit cells, such as in a top layer and a bottom layer of a multi-layer stack 300 (see above, FIG. 3A), in accordance with some embodiments. The top layer and the bottom layer may be adjacent layers 302 (see above, FIG. 3A). A unit cell comprises a dual-row differential pair Moiré grating design. In various embodiments, the unit cells have widths W₃ (see above, FIG. 3A) and lengths L₂ in a range of 1 μm to 100 μm. A grating p₁ in the top layer and a grating p₂ in the bottom layer form a first Moiré interference pattern. The p₂ grating in the top layer and the p₁ grating in the bottom layer will form a second Moiré interference pattern. Notations p₁ and p₂ refer to grating pitches of the gratings. Individual gratings or groups of gratings in a layer, which form a Moiré interference pattern with another grating or group of gratings in a different layer may hereinafter be referred to as sections, alignment sections, or as bonded pair fiducials. For a Moiré pattern to be formed, the pitches of gratings p₁ and p₂ are desirably different but within the coherence length of the X-ray system for interference to take place. The two Moiré patterns generated by the two pairs p₁-p₂ (the first pair for −X fiducials direction) and p₂-p₁ (the second pair for +X fiducials direction) of the unit cell are the same if there is no misalignment between the top layer and the bottom layer. However, when there is a misalignment, the two Moiré patterns will shift in opposite directions (−X and +X directions), and the difference between the shifts can be correlated with the amount of layer misalignment, thereby forming the basis for alignment metrology for a single direction. Similarly, bonded pair fiducials can be formed for the −Y and +Y directions, or at any desired angle such as 45 degrees. To form a Moiré pattern, X-rays are desirably spatially coherent on the bonding fiducial mark length scale or greater and incident on a unit cell comprised of bonding fiducial marks such that the X-ray path is aligned with the grating pattern (in other words, the Moiré grating direction should be aligned with the Talbot-Lau grating). To enable imaging of Moiré patterns from both unit cells and thus enable determination of misalignment in both +/−X and +/−Y directions, the multi-layer stack is printed rotated 90° in the bonded pair and imaged with said rotation to ensure the linear grating is aligned requiring taking two X-ray images. Alternatively, the +/−X and +/−Y unit cells are imaged in one X-ray image by rotating the optical axis of the X-ray imaging system with respect to the bonded pair surface normal (substrate axis) to achieve a relative rotation of 45 degrees. In the latter, there is a component of the linear grating for Talbot Lau that aligns with both X and Y unit cell directions. Alternatively, the X-ray source and imaging system gratings are rotated with respect to the multi-layer stack by 90 degrees to capture both orthogonal directions of the X and Y unit cell gratings. Without loss of specificity, a 2D X-ray Talbot Lau grating can be generated and matched with 2D Moiré dual differential gratings that capture both X and Y direction information. The advantage of the latter is that the entire unit cell area can be utilized to print a single 2D grating instead of using half the area for the X direction and half the area for the Y direction.

In other embodiments, the X-ray source azimuthal position is adjusted to illuminate the unit cell gratings at an angle of about 45° with respect to the grating pattern, forming Moiré patterns on both horizontal and vertical grating pairs simultaneously, and thus allowing misalignment in both x and y directions to be determined from a single image. The former approach may increase sensitivity, while the latter approach may increase throughput.

FIGS. 5A, 5B, and 5C illustrate correlation of misalignment between layers with Moiré pattern shift of the bonded pair bonding fiducial marks, in accordance with some embodiments. FIG. 5A illustrates simulated X-ray image results of the dual-row differential pair Moiré grating design with programmed misalignment of 0, Δx, 2Δx and 3Δx. Without loss of generality, the method will be described for an example of a linear Talbot Lau grating system. The method may be practiced by a variety of X-ray architectures, for example, a 2D Talbot Lau grating system, or no gratings utilizing a highly collimated and spatially coherent X-ray beam derived from sources such as synchrotrons, betatrons, inverse Compton sources, or conventional sources using collimating X-ray optics. In FIG. 5A, pₘ is the Moiré pattern pitch, Δx is the actual (or programmed, in a simulation) misalignment between layers, and ΔX is the Moiré pattern shift (in other words, from a position in which alignment is perfect with Δx=0). Simulations are shown for perfect layer alignment (Δx=0), and for gradually increasing layer misalignment Δx, 2Δx, and 3Δx. The rightmost plot in FIG. 5A illustrates Moiré patterns generated by two grating pairs forming bonding fiducial marks for a bonded pair and moving apart in opposite directions as misalignment is increased for the bonded pair. Because of movement in opposite directions, the total Moiré pattern shift Δx is two times the individual Moiré pattern shift of any single grating pair.

FIG. 5B illustrates Talbot-Lau multi-modality X-ray images of transmission, differential phase contrast, and small angle scatter images. In various embodiments, systems can take such images taken simultaneously, or in other words, in a single shot. FIG. 5C illustrates a correlation between a misalignment Δx within the bonded pair and a Moiré pattern shift ΔX that is linear. The coefficient relating the misalignment Δx and Moiré pattern shift ΔX is the Moiré magnification factor, enabling a micron scale X-ray imaging system to detect nm scale overlay misalignment within a bonded pair in a multi-die stack. The Moiré magnification factor allows determination of nanometer-level misalignments by imaging micron-level Moiré pattern shifts in deriving figures of merit from the detected X-ray images and calculating phase shift (or differential phase shift) and small-angle scatter changes (dark-field X-ray). The lower limit of detection 310 is the smallest misalignment between layers that can be detected, and the upper limit of detection 320 is the largest misalignment between layers that can be detected.

FIG. 6 illustrates a contrast improvement method that may be used when an alignment mark thickness T₂ is small. When the alignment mark thickness T₂ is small, the alignment mark introduces a very small amount of amplitude and phase modulation to the incident X-ray beam. In some embodiment, normalization is introduced, such as rescaling X-ray image pixel intensities to the range [0,1], to help enhance contrast so small misalignments could be more accurately detected. This is illustrated in the X-ray small angle scatter image of FIG. 6. Alternatively, the method of combining additional thickness to the fiducial marks in the top target die and bottom substrate (a wafer or previous die to wafer bonded pair(s)) by using redistribution layer (RDL) Cu metal can also enhance the signal to noise ratio by increasing the optical path length through the added Cu, increasing the phase shift or small angle X-ray scattering (SAXS).

FIG. 7 illustrates shows a side view of an alignment mark layout system for a normal incidence X-ray beam, in accordance with some embodiments. Layers 302-1, 302-2, and 302-3 through 302-15 are all to be aligned with a reference layer 302-16 (in other words, the layer to which all other layers are aligned and/or registered). The vertical axis z is normal to the layers of the multi-layer stack, and the horizonal axes x and y are in a plane parallel with the layers of the multi-layer stack.

As illustrated by FIG. 7, the reference layer 302-16 is the bottommost layer of the multi-layer stack, but the reference layer 302-16 is not required to be the bottommost layer 16 and can be in any suitable position in the multi-layer stack. The respective alignment marks 304-1, 304-2, and 304-3 through 304-15 on each layer 302-1, 302-2, and 302-3 through 302-15 are aligned along respective X-ray paths for a normal incidence X-ray beam over corresponding alignment marks 304-1′, 304-2′, and 304-3′ through 304-15′ on the reference layer 302-16. The alignment marks 304-1, 304-2, and 304-3 through 304-15 are spatially separated so misalignment between any of 302-1, 302-2, and 302-3 through 302-15 and with the reference layer 302-16 can be detected independent of alignment of other pairs of layers. Although FIG. 7 illustrates an alignment mark layout for a multi-layer stack with 16 layers, the described alignment mark layout system may be used for multi-layer stacks with any suitable number of layers, such as 3 to 15 layers, or more than 16 layers. The latter enables the practice of monitoring the tolerance stack-up error that may accumulate as additional layers are bonded and applying feedforward correction to the next set of dies (or other layers) to be bonded.

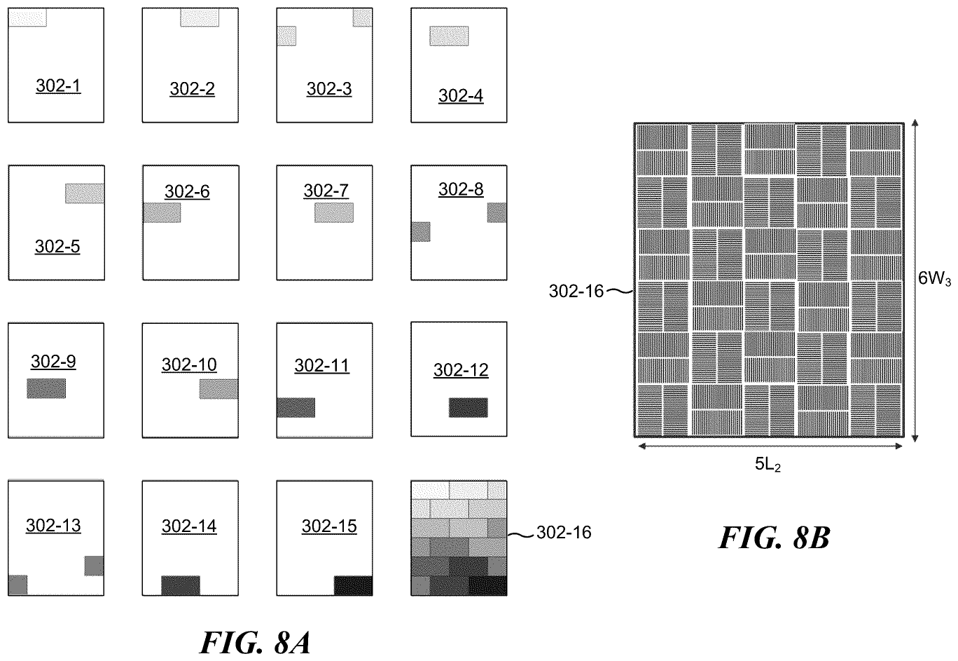

Next, FIGS. 8A, 8B, 9A, 9B, 10A, 10B and 11 illustrate embodiments of alignment mark layouts. FIGS. 8A and 8B illustrate a top view of a double basketweave embodiment of an alignment mark layout for a normal incidence X-ray beam. FIG. 8A illustrates top views of layers 302-1 to 302-15 of a multi-layer stack (e.g., the multi-layer stack 300; see above, FIG. 3A), each comprising a respective individual alignment mark that is aligned with a corresponding alignment mark on reference layer 302-16, as depicted with varying gray-scale shades. All alignment marks of layers 302-1 to 302-15 are spatially separated. Although the alignment mark layouts are different for all 16 layers, the total size of the alignment mark area is the same in all 16 layers. When any pair of alignment marks of two layers are aligned, there is no other pattern along an X-ray path between the two layers of the pair.

FIG. 8B further illustrates the alignment mark layout of reference layer 302-16, which contains all the alignment mark layouts of layers 302-1 to 302-15 above it. The alignment mark unit cell utilized in this embodiment is illustrated above in FIG. 4. In some embodiments, the total alignment mark size in this embodiment is 6W₃×5L₂. In an embodiment, the alignment mark width W₃ equals the alignment mark length L₂.

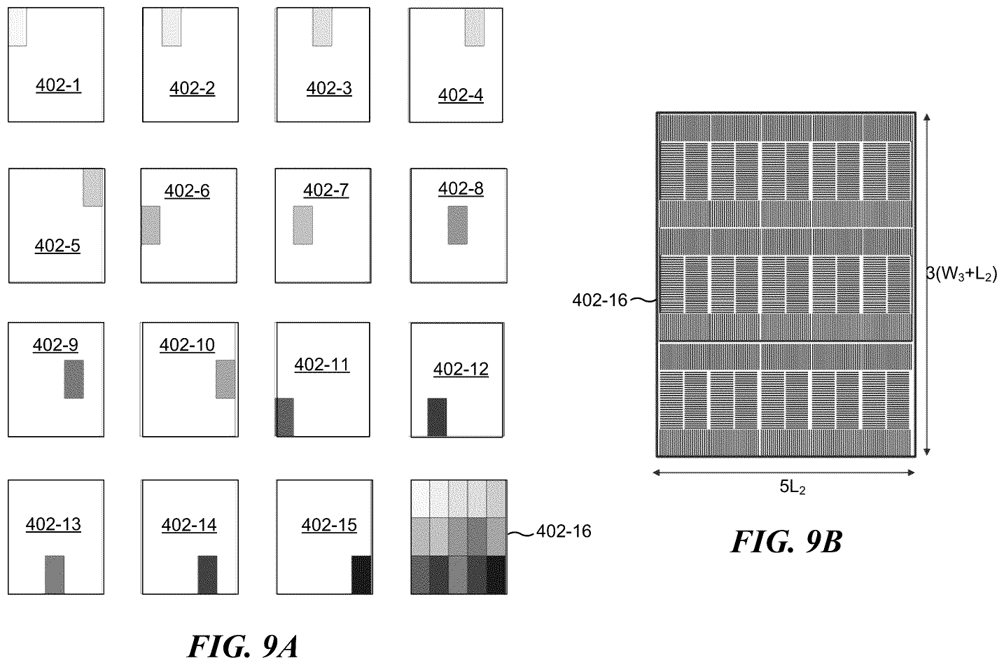

Next, FIGS. 9A and 9B illustrate top views of a combination stacked/running bond embodiment of an alignment mark layout for a normal incidence X-ray beam. FIG. 9A illustrates top views of layers 402-1 to 402-15 of a multi-layer stack, each comprising a respective individual alignment mark that is aligned with a corresponding alignment mark on reference layer 402-16, as depicted with varying gray-scale shades, with all alignment marks being spatially separated. Although the alignment mark layouts are different for all 16 layers, the total size of the alignment mark area is the same in all 16 layers. When any pair of alignment marks of two layers are aligned, there is no other pattern along an X-ray path between the two layers of the pair.

FIG. 9B further illustrates the alignment mark layout of reference layer 402-16, which contains all the alignment mark layouts of layers 402-1 to 402-15 above it. The alignment mark unit cell utilized in this embodiment is illustrated above in FIG. 4. In some embodiments, the total alignment mark size in this embodiment is 3(W₃+L₂)×5L₂. In an embodiment, the alignment mark width W₃ equals the alignment mark length L₂.

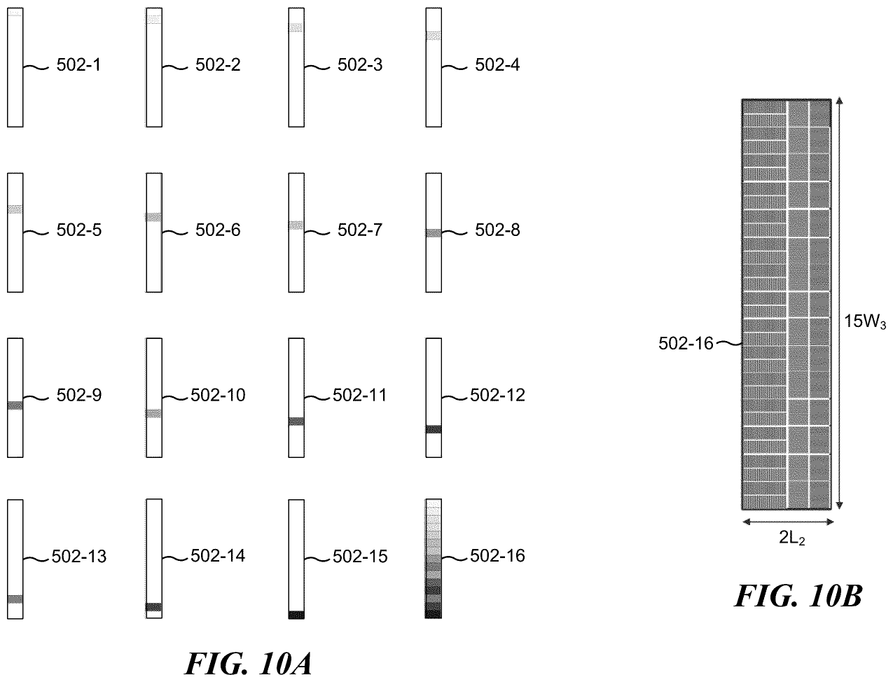

Next, FIGS. 10A and 10B illustrate top views of a of a stack bond embodiment of an alignment mark layout for a normal incidence X-ray beam. FIG. 10A illustrates top views of layers 502-1 to 502-15 of a multi-layer stack, each comprising a respective individual alignment mark that is aligned with a corresponding alignment mark on reference layer 502-16, as depicted with varying gray-scale shades, with all alignment marks being spatially separated. Although the alignment mark layouts are different for all 16 layers, the total size of the alignment mark area is the same in all 16 layers. When any pair of alignment marks of two layers are aligned, there is no other pattern along an X-ray path between the two layers of the pair.

FIG. 10B further illustrates the alignment mark layout of reference layer 502-16, which contains all the alignment mark layouts of layers 502-1 to 502-15 above it. The alignment mark unit cell utilized in this embodiment is illustrated above in FIG. 4. In some embodiments, the total alignment mark size in this embodiment is 15W₃×2L₂. In an embodiment, the alignment mark width W₃ equals the alignment mark length L₂.

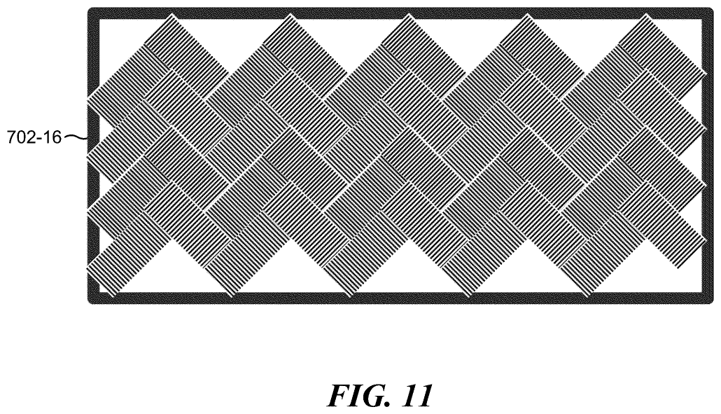

The choice of alignment mark embodiment to use may be determined by the amount of space available within the die. For example, the double basketweave and combination stack/running bond alignment marks of FIGS. 8A-8B and 9A-9B may be well suited to die with rectangular areas available for their placement. The stack bond alignment mark of FIGS. 10A-10B may be well suited for location at die edges, owing to its elongated shape. Additionally, other embodiments of alignment mark layouts may be used. For example, FIG. 11 illustrates a reference layer 702-16 with a 45 degree herringbone layout of reference alignment marks. Any suitable layout for alignment marks may be used, and all such layouts are within the scope of the disclosed embodiments.

The alignment mark layout systems for normal incidence X-ray beams include different alignment mark pattern on each layer or die, which may introduce fabrication complexity and increase cost. However, these alignment mark layout systems allow for precise layer alignment and registration because each alignment mark in body layers of a multi-layer stack (for example, layers 1 through 15) is aligned independently with respect to the alignment mark in the reference layer of the multi-layer stack (for example, layer 16). The misalignment measurement of one layer, and errors associated with that measurement do not affect other misalignment measurements in the stack. As such, layer 16 (or some other layer, in other embodiments) serves as a reference layer for alignment of all layers in the stack, minimizing the tolerance stack-up error in bonded pairs.

Further embodiments using oblique incidence X-rays may reduce fabrication complexity and decrease cost by using a single layout for the fiducial mark to be printed for each layer, thereby reducing the number of lithography masks to produce for die stack devices of 16 dies or more), and the alignment marks will have smaller sizes than the relatively large size of the alignment marks in embodiments utilizing normal incidence X-rays. FIGS. 12A, 12B, 13A, and 13B illustrate an alignment mark unit cell design for an oblique incidence X-ray beam with a source tilted at angle θ, in accordance with some embodiments.

FIG. 12A illustrates an alignment mark design 800 (also referred to as a unit cell design) to be used with an oblique incidence X-ray beam. An advantage of oblique incidence X-ray illumination is that the alignment mark on each layer is the same, which reduces fabrication complexity and cost. The alignment mark design 800 comprises a left section 800A and a right section 800B. Because of the angled projection, the pitches of the gratings p₃ and p₄ will be smaller compared to the pitches of the gratings p₁ and p₂ in a normal incidence embodiment (see above, FIG. 4). This may be considered in alignment mark design. For example, the pitches of the gratings p₃ and p₄ may be smaller by a factor of 1/cos θ, where θ is the angle of the tilt of the source as illustrated in FIG. 12B.

FIG. 12B illustrates a side view of alignment marks on two adjacent layers of a multi-layer stack. The top layer has an alignment mark with a left section 800A-N and a right section 800B-N, and the bottom layer has an alignment mark with a left section 800A-N+1 and a right section 800B-N+1. To use the same alignment mark in all layers, the left section 800A-N of the alignment mark of layer N overlaps with the right section 800B-N+1 of layer N+1 along an X-ray beam path to form a Moiré pattern on the X-ray detector. This requirement governs the relationship between the tilt angle θ and the alignment mark width W₂=2W₃, the alignment mark thickness T₂, and layer (or target die) thickness T₁, as illustrated in FIG. 12B. In many applications, the alignment mark thickness T₂ is much smaller than the layer thickness T₁ such that T₂<<T₁ and the tangent of the tilt angle tan θ is about W₃/T₁. θ determines the desired tilt angle of the X-ray source, which is important in the design of the hardware. For example, if θ is large, then the whole imaging footprint will be big. Exemplary values in various embodiments include a thickness T₂ of about 0.25 μm and a thickness T₁ of about 35 μm.

FIGS. 13A and 13B illustrate an alignment mark system for an oblique incidence X-ray beam with a source tilted at an angle θ (described above with respect to FIG. 12B) utilizing the unit cell design of FIGS. 12A and 12B, in accordance with some embodiments. FIG. 13A is a simplified schematic of the tilted X-ray source projection imaging system. A multi-layer stack has sixteen layers 802-1 through 802-16, each having a respective alignment mark with a left section 800A and a right section 800B aligned over each other vertically. An X-ray source 810 is positioned to deliver X-rays through the multi-layer stack at an oblique incidence angle (e.g., an angle incidence angle θ) to an X-ray detector 814 opposite the X-ray source 810. With a plane X-ray wavefront at an incidence angle θ and with the alignment marks meeting the conditions described above with respect to FIG. 12B, namely that the left section 800A of a top layer mask overlaps with the right section 800B of the bottom layer mask along the projected X-ray beam path, the resultant images will be spatially separated in

FIG. 13B shows a detector image 820 having sixteen regions. The leftmost and rightmost regions of the detector image 820 are non-Moiré patterns because they correspond to the left section 804-16A of the layer 802-16 alignment mark and the right section 804-1B of the layer 802-1 alignment mark, respectively, which do not form a pair with an alignment mark on another layer. All other regions are Moiré patterns corresponding to different pairs of adjacent layers. For example, the second from the rightmost region of the detector image 820 corresponds to the sections 804-2B and 804-1A, the third from the rightmost region of the detector image 820 corresponds to the sections 804-3B and 804-2A, the nth from the rightmost region of the detector image 820 corresponds to the sections 804-NB and 804-(N−1)A, and the (n+1)th rightmost region of the detector image 820 corresponds to the sections 804-(N+1)B and 804-NA. Hence, misalignment in any pair of two adjacent layers can be detected. In alignment mark systems in accordance with these embodiments, misalignment is not measured with respect to a single reference layer as in embodiments with normal X-ray incidence (see above, FIGS. 7-11), but rather misalignment of each layer with respect to its neighboring layers, such as layers above and below it in the multi-layer stack, is measured. As such, determining the misalignment of any one of the layers 802-1 to 802-15 with respect to, for example, layer 802-16 may be achieving by adding the measured misalignments of all intervening pairs of layers. Although the alignment mark system for an oblique incidence X-ray beam is described with respect to an exemplary sixteen layer multi-layer stack, it may be applied to any multi-layer stack with three or more layers, and all such systems and structures are within the scope of the disclosed embodiments. Alternatively, alignment mark design 800, printed within all 16 layers, may be used in normal incidence to measure a “go/no-go” statistical process control figure of merit (FOM), and then the oblique view can be used when an outlier is detected in the FOM during production monitoring. The FOM may be a contrast function that detects when a measurable Moiré fringe appears due to the misalignment of all marks in the 16 layers and may be derived from intensity or phase information.

The disclosed alignment mark layout systems described above with respect to FIGS. 3A, 3B, 4, 5A, 5B, 5C, and 6, the disclosed alignment mark layout systems for normal incidence X-ray beam described above with respect to FIGS. 7, 8A, 8B, 9A, 9B, 10A, 10B, and 11, and the disclosed alignment mark layout systems for an oblique incidence X-ray beam described above with respect to FIGS. 12A, 12B, 13A, and 13B may be used in combination with the X-ray detection systems described above with respect to FIGS. 1 and 2A, or in combination with any other suitable X-ray detection systems. All such combinations are within the scope of the disclosed embodiments.

X-ray metrology systems for measuring misalignment of layers in a bonded die stack in accordance with embodiments described herein may advantageously be used for defect inspection of bonded pairs to a substrate. Such X-ray metrology systems would uniquely be able to combine their layer (die) ID capability with the ability to detect common bonding defects such as voids, cracks, delamination, foreign material between Cu pads, foreign material between insulator layers (Si—C—N, SiNx, TEOS, SiOx), diffusion of Cu into the insulating layer, and incomplete Cu—Cu contacts due bow/warp or improper bonding conditions, or alternatively, to generate quality binning represent a grade across the final bonded wafer. In various examples, 5 bins for quality are defined for HBM memory, and the entire device wafer can be traceable for product separation. The lower quality chips are used in less-demanding applications, while the highest quality chips are used in the most demanding applications, where failure is not an option, e.g., in self-driving automotive AI, or in aerospace and defense applications, etc. This is advantageous for ensuring the overall electrical performance, yield, and long-term reliability of devices by quality type. The ability to detect and classify defects such as voids, cracks, delamination, foreign material in various interfaces, and incomplete bonding of various kinds is useful for ensuring that only high-quality die stacks proceed forward in the manufacturing process, and binned by their acceptable levels of defectivity and misalignment.

The systems described herein achieve alignment precision down to the nanometer scale using multi-die Moiré pattern interference with a Moiré magnification factor, whilst maintaining reliable detection of larger-scale misalignments using conventional concentric squares, cross in cross, or box in box patterns. They also can provide real-time feedback/feedforward during bonding for immediate correction of detected misalignments prior to completing a multi-die device, support post-bonding validation, and enable decisions such as rework, binning, or downgrading of the die stacks, including rejection to avoid bonding bad stacks to “good known stacks”, especially for HBM or Advanced DRAM memory devices that may be manufactured in a series of stacking “known good stacks” (for example, bonded stacks of 4 layers or 8 layers to build up to 16 layers in 2 or more bonding steps).

Advantageously, the use of multi-die Moiré patterns allows for nanometerscale detection of shifts or misalignment with a Moiré magnification factor and identification of the specific layers within the die stack that are misaligned. This is critical for processes where multiple dies are stacked simultaneously, where a large number of dies are individually stacked together with, for example, more than 16 dies within a single stack, or where multiple layers are stacked and bonded together to form “good known stacks” that are subsequently stacked and bonded to form larger stacks of 16 or more layers, as described before.

FIG. 14 illustrates a process flow chart diagram of a method 4000 for multi-layer alignment, in accordance with some embodiments. In step 4002, a respective alignment mark is applied to each layer of a plurality of layers, as described above with respect to FIG. 3A. The plurality of layers comprises at least three layers. In step 4004, X-rays are directed to the respective alignment marks of each layer of the plurality of layers, as described above with respect to FIGS. 1, 2A, 7, and 13A. The plurality of layers is in a bonding configuration. In step 4006, a misaligned layer in the plurality of layers is identified by measuring interference patterns generated by the X-rays, as described above with respect to FIGS. 5A, 5B, and 5C. In some embodiments, the misalignment of the misaligned layer is a horizontal, vertical, or rotational misalignment. In some embodiments, defects are detected in the plurality of layers with the X-rays. In some embodiments, real-time feedback for correction of misalignment in the plurality of layers using the measured interference patterns is provided and is subsequently utilized to move the x, y and theta errors back towards “zero” when adding the next set of “known good stack”, also referred to as feedforward correction.

Embodiments may be further applied to alignment mark systems including more than two gratings, such as three or four gratings. There are often many metal layers in a bonded device besides the bonding layers, such as redistribution layers (RDLs). In advanced packaging, the number of RDLs can be up to seven. Taking advantage of these metal layers using three or four gratings in addition to the two grating fiducials discussed can be beneficial because the total effective metal thickness is increased. For example, in the four-grating configuration, two gratings with pitches p₁ and p₂ can be patterned on the RDL and bonding metal layers of the top die, forming a first Moiré pattern. On the bottom die or substrate, the gratings with pitches p₂ and p₁ can be similarly patterned to form a second Moiré pattern. When there is no misalignment, the two Moiré patterns overlap, strengthening the signal due to the increased total thickness. However, when there is misalignment, the two Moiré patterns will shift relative to each other, generating a measurable displacement signal. In the three-grating configuration, two gratings with pitches p₁ and p₂ are patterned on the RDL and bonding metal layers of the top die, while a third grating with pitch p₃ is patterned on the bonding metal layer of the bottom substrate. The combination of these three gratings generates higher-order Moiré interference patterns, which produce an even higher Moiré magnification factor. This configuration enables a lower limit of detection (as described above with respect to FIG. 5C) for misalignment. However, it is noted that higher-order modulations may have reduced signal strength compared to first-order Moiré interference signals.

Example embodiments of the disclosure are summarized here. Other embodiments can also be understood from the entirety of the specification as well as the claims filed herein.
Example 1. A semiconductor structure including: a first layer, a second layer, and a third layer bonded together in a multi-layer stack, the first layer including a first alignment section, the second layer including a second alignment section, and the third layer including a third alignment section and a fourth alignment section, the third alignment section being along a first X-ray path with the first alignment section, and the fourth alignment section being along a second X-ray path with the second alignment section.
Example 2. The semiconductor structure of example 1, where the first X-ray path and the second X-ray path are normal to a plane of the first alignment section.
Example 3. The semiconductor structure of example 1, where the first X-ray path and the second X-ray path are at an oblique angle with a plane of the first alignment section.
Example 4. The semiconductor structure of one of examples 1 or 2, where the first layer is over the second layer and the second layer is over the third layer.
Example 5. The semiconductor structure of one of examples 1 or 3, where the first layer is over the third layer and the third layer is over the second layer.
Example 6. The semiconductor structure of one of examples 1 to 5, where the multi-layer stack further includes a fourth layer, the fourth layer including a fifth alignment section.
Example 7. The semiconductor structure of example 6, where the third layer further includes a sixth alignment section, the sixth alignment section being along a third X-ray path with the fifth alignment section.
Example 8. The semiconductor structure of example 6, where the second layer further includes a sixth alignment section, the sixth alignment section being along a third X-ray path with the fifth alignment section.
Example 9. The semiconductor structure of one of examples 1 to 8, where the first alignment section, the second alignment section, the third alignment section, and the fourth alignment section are Moiré patterns.
Example 10. The semiconductor structure of one of examples 1 to 9, where the first alignment section, the second alignment section, the third alignment section, and the fourth alignment section include a metal.
Example 11. The semiconductor structure of one of examples 1 to 10, where the multi-layer stack further includes a fourth layer through a sixteenth layer.
Example 12. The semiconductor structure of example 11, where each layer of the fourth layer through the sixteenth layer includes a respective alignment section.
Example 13. A method for multi-layer alignment, the method including: applying a respective alignment mark to each layer of a plurality of layers, the plurality of layers including at least three layers; directing X-rays to the respective alignment marks of each layer of the plurality of layers, the plurality of layers being in a bonding configuration; and identifying a misaligned layer in the plurality of layers by measuring interference patterns generated by the X-ray.
Example 14. The method of example 13, where the misalignment is a horizontal, vertical, or rotational misalignment.
Example 15. The method of one of examples 13 or 14, further including detecting defects in the plurality of layers with the X-ray.
Example 16. The method of one of examples 13 to 15, further including providing real-time feedback for correction of misalignment in the plurality of layers using the measured interference patterns.
Example 17. The method of one of examples 13 to 16, further including: bonding the plurality of layers; and performing post-bonding validation of the plurality of layers using the measured interference patterns.
Example 18. A system for multi-layer alignment including: a multi-layer stack, the multi-layer stack including a plurality of layers in a bonding configuration, each layer of the plurality of layers including a respective Moiré alignment mark; and an X-ray imager configured to: direct X-rays to the respective Moiré alignment marks, and identify a misaligned layer in the plurality of layers by measuring interference patterns generated by the X-rays.
Example 19. The system of example 18, where the X-ray imager is a Talbot-Lau multi-modal imager.
Example 20. The system of example 18, where the X-ray imager is a propagation-based imager configured to use spatially coherent collimated X-rays.
Example 21. The system of one of examples 18 to 20, where the X-ray imager has a projection transmission mode architecture that utilizes spatially coherent X-rays or small angle-scattered X-rays.
Example 22. The system of one of examples 18 to 20, where the X-ray imager has a reflection mode diffractometer architecture that utilizes spatially coherent X-rays or small angle-scattered X-rays.
Example 23. The system of one of examples 18 to 22, where the X-ray imager is further configured to remove absorption cross-section across a full range of energies in its illumination spectrum.
Example 24. The system of one of examples 18 to 23, where the X-ray imager is further configured to utilize phase coherence or small angle-scattered X-rays for a memory and LSI logic radiation damage free probe to identify the misaligned layer.
Example 25. The system of one of examples 18 to 24, where the X-ray imager is further configured to perform defect detection.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A semiconductor structure comprising:
a first layer, a second layer, and a third layer bonded together in a multi-layer stack, the first layer comprising a first alignment section, the second layer comprising a second alignment section, and the third layer comprising a third alignment section and a fourth alignment section, the third alignment section being along a first X-ray path with the first alignment section, and the fourth alignment section being along a second X-ray path with the second alignment section.

2. The semiconductor structure of claim 1, wherein the first X-ray path and the second X-ray path are normal to a plane of the first alignment section.

3. The semiconductor structure of claim 1, wherein the first X-ray path and the second X-ray path are at an oblique angle with a plane of the first alignment section.

4. The semiconductor structure of claim 1, wherein the first layer is over the second layer and the second layer is over the third layer.

5. The semiconductor structure of claim 1, wherein the first layer is over the third layer and the third layer is over the second layer.

6. The semiconductor structure of claim 1, wherein the multi-layer stack further comprises a fourth layer, the fourth layer comprising a fifth alignment section.

7. The semiconductor structure of claim 6, wherein the third layer further comprises a sixth alignment section, the sixth alignment section being along a third X-ray path with the fifth alignment section.

8. The semiconductor structure of claim 6, wherein the second layer further comprises a sixth alignment section, the sixth alignment section being along a third X-ray path with the fifth alignment section.

9. The semiconductor structure of claim 1, wherein the first alignment section, the second alignment section, the third alignment section, and the fourth alignment section are Moiré patterns.

10. The semiconductor structure of claim 1, wherein the first alignment section, the second alignment section, the third alignment section, and the fourth alignment section comprise a metal.

11. The semiconductor structure of claim 1, wherein the multi-layer stack further comprises a fourth layer through a sixteenth layer.

12. The semiconductor structure of claim 11, wherein each layer of the fourth layer through the sixteenth layer comprises a respective alignment section.

13. A method for multi-layer alignment, the method comprising:
applying a respective alignment mark to each layer of a plurality of layers, the plurality of layers comprising at least three layers;
directing X-rays to the respective alignment marks of each layer of the plurality of layers, the plurality of layers being in a bonding configuration; and
identifying a misaligned layer in the plurality of layers by measuring interference patterns generated by the X-rays.

14. The method of claim 13, wherein the misalignment is a horizontal, vertical, or rotational misalignment.

15. The method of claim 13, further comprising detecting defects in the plurality of layers with the X-rays.

16. The method of claim 13, further comprising providing real-time feedback for correction of misalignment in the plurality of layers using the measured interference patterns.

17. The method of claim 13, further comprising:
bonding the plurality of layers; and
performing post-bonding validation of the plurality of layers using the measured interference patterns.

18. A system for multi-layer alignment comprising:
a multi-layer stack, the multi-layer stack comprising a plurality of layers in a bonding configuration, each layer of the plurality of layers comprising a respective Moiré alignment mark; and
an X-ray imager configured to:
direct X-rays to the respective Moiré alignment marks, and
identify a misaligned layer in the plurality of layers by measuring interference patterns generated by the X-rays.

19. The system of claim 18, wherein the X-ray imager is a Talbot-Lau multi-modal imager.

20. The system of claim 18, wherein the X-ray imager is a propagation-based imager configured to use spatially coherent collimated X-rays.
